(19) United States
(12) Patent Application Publication
(10) Pub. No.: US 2009/0086113 A1
(43) Pub. Date: Apr. 2, 2009

(54) TOUCH PANEL AND TOUCH LIQUID CRYSTAL DISPLAY USING THE SAME

(75) Inventors: Han-Ching Ko, Taipei County (TW); Min-Hung Chang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/203,930

(22) Filed: Sep. 4, 2008

(30) Foreign Application Priority Data
Sep. 29, 2007 (TW) 96136575

(51) Int. Cl. G02F 1/1335; H03K 17/975

(52) U.S. Cl. 349/12; 200/600

(57) ABSTRACT

A touch panel and a touch liquid crystal display (LCD) using the touch panel are provided. The structure of the touch panel is directly formed on an upper polarizer instead of a glass substrate. Thereby, the process of integrating the touch panel and an LCD panel is simplified and the glass substrate of the touch panel is eliminated. Thus, the cost, the thickness and the weight of the touch LCD are reduced.

### CROSS-REFERENCE TO RELATED APPLICATION

This application claims the priority benefit of Taiwan application serial no. 96136575, filed on Sep. 29, 2007. The entirety of the above-mentioned patent application is hereby incorporated by reference herein and made a part of specification.

### BACKGROUND OF THE INVENTION

1. Field of the Invention

The present invention relates to a touch panel. More particularly, the present invention relates to a touch panel using a polarizer instead of a glass substrate and a liquid crystal display (LCD) using the touch panel (abbreviated as a touch LCD).

2. Description of Related Art

Touch panel is an interface tool for information exchange and is widely accepted by the public. Currently, the widely employed touch panels are mainly classified into two types, i.e., resistive touch panels and capacitive touch panels. The structure of the touch panel is mostly formed by a polyethylene terephthalate (PET) film and a layer of glass, and then the touch panel is adhered onto a liquid crystal panel by glues. FIG. 1 is a structure diagram of a resistive touch panel in conventional art. A touch panel 100 is mainly contained a PET film 110, spacer dots 120, and a glass layer 130, and the spacer dots 120 form an intermediate layer for spacing the PET film 110 from the glass layer 130. Both surface of the PET film 110 and the glass layer 130 are developed by the transparent electrode wires using indium tin oxide (ITO), so as to transmit electrical signals. In the touch panel 100, a glue is generally used to adhere the glass layer 130 and an upper polarizer 140 of the liquid crystal panel (other structures of the liquid crystal panel are not shown), and the arrangement structure is as shown in FIG. 1.

As the glass layer 130 of the touch panel 100 is too heavy and thick, it is not suitable for being used in portable products such as notebooks. However, if the touch panel is formed by two PET films, the transmittance would be influenced. Furthermore, it is difficult to control the process quality due to poor adhesion of indium tin oxide (ITO) on the PET film.

Additionally, Taiwan Patent No. I223116 disclosed a liquid crystal display (LCD) device with a built-in touch panel and the manufacturing process thereof, in which the touch panel is formed between an upper polarizer and an upper glass substrate of an LCD display unit, while the polarizer is not designed for being pressed. Thus, the sensitivity of the contact points would be affected, and at the same time the polarizer would be damaged. Additionally, the upper polarizer is fully adhered on the PET film, while the PET is adhered on the color filter in the state of surrounding adhesion. Thus, edge mura or conner mura on polarizer is generated. Further, as the touch panel is formed between the upper polarizer and the upper glass substrate of the LCD display unit, the touch panel is difficult to maintain due to some damages. And the whole display panel might be discarded. Therefore, during the process conditions presently, if the touch panel is integrated into the liquid crystal panel, and the glass substrate is eliminated, the weight, the volume, and the cost of the touch panel would be effectively reduced.

### SUMMARY OF THE INVENTION

Accordingly, the present invention is directed to provide a touch panel, in which the touch panel is directly integrated in the structure of an LCD by using a polarizer instead of a glass substrate.

The present invention is further directed to provide a touch LCD, which can directly form a touch panel on a polarizer. As the result, it's making the touch LCD lighter and thinner, and reducing the cost of design.

The present invention provides a touch panel, which includes a polarizer, a contact layer, and an intermediate layer. The polarizer has a plurality of first electrodes, and the contact layer has a plurality of second electrodes. The intermediate layer is disposed between the polarizer and the contact layer for spacing the polarizer from the contact layer. The contact layer can be made of PET film, and the desired first electrodes and second electrodes can be respectively formed on the surface of the contact layer and the polarizer by using indium tin oxide (ITO). In an embodiment of the present invention, the intermediate layer includes a plurality of spacer dots for spacing the polarizer from the contact layer.

The present invention provides a touch panel, which includes a polarizer, a conductive layer, an electrode pattern layer, and a protective layer. The conductive layer is disposed on the polarizer, the electrode pattern layer has a plurality of first electrodes and second electrodes on upper and lower surfaces thereof respectively, the electrode pattern layer is disposed on the conductive layer, and the protective layer is disposed on the electrode pattern layer to protect the electrode pattern layer.

The present invention provides a touch LCD which includes a lower polarizer, an LCD display unit, an upper polarizer, a contact layer, and an intermediate layer. The upper polarizer and the lower polarizer are respectively disposed on the both sides of the LCD display unit, and the upper polarizer has a plurality of first electrodes which is opposite to the LCD display unit. The contact layer has a plurality of second electrodes, and is disposed on the upper polarizer. The intermediate layer is disposed between the upper polarizer and the contact layer for spacing the first electrodes from the second electrodes. The structure formed by the upper polarizer, the intermediate layer, and the contact layer has the functions of a touch panel.

The present invention further provides a touch LCD, which includes a lower polarizer, an LCD display unit, an upper polarizer, a conductive layer, an electrode pattern layer, and a protective layer. The upper polarizer and the lower polarizer are respectively disposed on the both sides of the LCD display unit, and the conductive layer is disposed on the upper polarizer. The electrode pattern layer has a plurality of first electrodes and second electrodes on upper and lower surfaces thereof respectively, the electrode pattern layer is disposed on the conductive layer, and the protective layer is disposed on the electrode pattern layer to protect the electrode pattern layer.

In another embodiment of the present invention, the LCD display unit at least includes a first substrate, a second substrate, and a lower polarizer. The upper polarizer is located on the surface of the first substrate, the lower polarizer is located on the surface of the second substrate, and the first substrate and the second substrate are disposed in opposite directions and are sandwiched together with liquid crystal.

As the present invention adopts a polarizer to replace the glass substrate required by the touch panel, the touch panel can be directly integrated into a liquid crystal panel. Thus a structure of a touch panel is directly formed on the upper polarizer of the liquid crystal panel, and the glass substrate. The process of adhering the touch panel and panel module are eliminated, such that the touch panel and the panel module have better fixity and uniformity.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a structure diagram of a resistive touch panel in conventional art.

FIG. 2 is a structure diagram of a resistive touch panel according to a first embodiment of the present invention.

FIG. 3 is a structure diagram of a capacitive touch panel according to a second embodiment of the present invention.

FIG. 4 is a structure diagram of a touch LCD according to a third embodiment of the present invention.

FIG. 5 is a structure diagram of a touch LCD according to a fourth embodiment of the present invention.

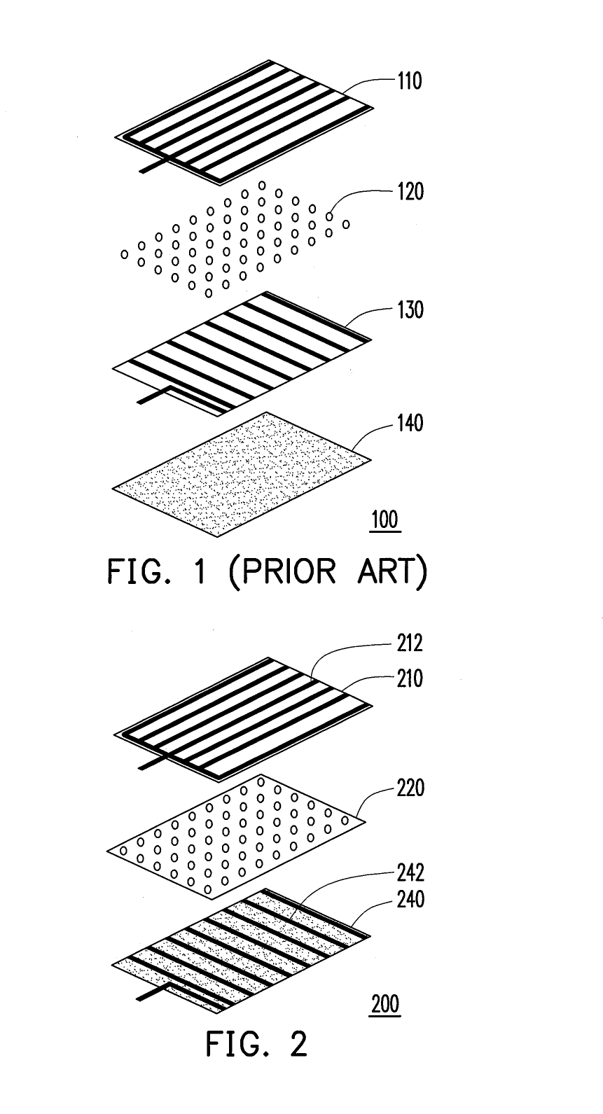

### DESCRIPTION OF EMBODIMENTS

### First Embodiment

FIG. 2 is a structure diagram of a resistive touch panel according to a first embodiment of the present invention. A touch panel 200 includes a contact layer 210, an intermediate layer 220, and a polarizer 240. The intermediate layer 220 is disposed between the contact layer 210 and the polarizer 240 for spacing the contact layer 210 from the polarizer 240. The contact layer 210 can be formed by PET film, glass or polymer film, so as to serve as a region for the user to contact the touch panel. The intermediate layer 220 is formed by spacer dots for spacing the polarizer 240 from the contact layer 210 when no force is applied on the contact layer 210. The polarizer 240 has a polarization function (i.e., limiting the angle of the passing light) and an electric signal transmitting function required by the touch panel.

The polarizer 240 has a plurality of first electrodes 242, and the contact layer 210 has a plurality of second electrodes 212. The first electrodes 242 and the second electrodes 212 can be replaced by transparent conductive electrodes formed by ITO, and the first electrodes 242 and the second electrodes 212 are disposed in opposite directions and are perpendicular to each other. When a force is applied to the contact layer 210 (for example, writing or pressing), the second electrodes 212 will contact with the first electrodes 242 to form channels, and the system can detect the pressing position through varies with current or voltage to, achieve the efficacy of the touch panel. Furthermore, the polarizer 240 in this embodiment can be directly replaced by the upper polarizer of LCD. That is to say, the first electrodes 242 are directly formed on the upper polarizer of the LCD. Accordingly, when the touch panel 200 and the LCD are integrated, a layer of glass substrate can be reduced compared to conventional touch LCD. Such that the touch LCD becomes lighter and thinner, and the cost of design is much lower.

### Second Embodiment

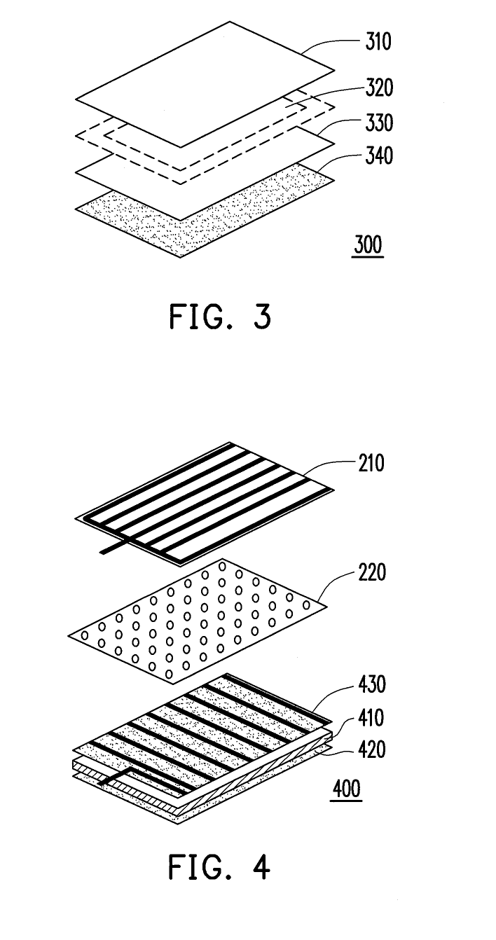

The technical method of the first embodiment can be applied in a capacitive touch panel. FIG. 3 is an architectural diagram of a capacitive touch panel according to a second embodiment of the present invention. The touch panel 300 includes a protective layer 310, an electrode pattern layer 320, a conductive layer 330, and a polarizer 340. The conductive layer 330 is disposed on the polarizer 340, and can be formed on the surface of the polarizer 340 directly by ITO. Such that the polarizer 340 has electromagnetic shielding effects. The electrode pattern layer 320 is disposed between the protective layer 310 and the conductive layer 330, and the electrode pattern layer 320 has a plurality of first electrodes and second electrodes on upper and lower surfaces thereof respectively, so as to form the desired electrode pattern. The protective layer 310 is disposed on the electrode pattern layer 320 to protect the electrode pattern layer 320.

In another embodiment of the present invention, the electrode pattern layer 320 can be formed by a glass substrate. The first electrodes and the second electrodes can be formed by coating a layer of conductive material, for example, an ITO or antimony doped tin dioxide (ATO) film, on the upper and the lower surfaces of the glass substrate, and then a protective scratch-resistant paint, for example, the protective layer 310, is coated thereon. As shown in FIG. 3, the structure of the touch panel 300 includes the protective layer 310, the electrode pattern layer 320, the conductive layer 330, and the polarizer 340 from top to bottom. The layers can be adhered together by conductive or nonconductive glues according to the design requirements, and the surrounding circuit wires can also be formed by silver paste film. The polarizer 340 in this embodiment can be directly replaced by the upper polarizer of LCD. That is to say, when integrating the touch panel and the LCD panel of this embodiment, the upper polarizer of the LCD panel can be directly used as the glass substrate of the touch panel. Compared with the conventional touch display panel, as a transmission layer is eliminated, the transmittance can be increased, and the weight is lighter and the thickness is thinner.

### Third Embodiment

FIG. 4 is a structure diagram of a touch LCD according to a third embodiment of the present invention. This embodiment further illustrates the structure relationship of a resistive touch panel integrated with an LCD panel. An LCD 400 includes a lower polarizer 420, an LCD display unit 410, an upper polarizer 430, a contact layer 210, and an intermediate layer 220. The touch panel is formed by the upper polarizer 430, the contact layer 210 and the intermediate layer 220, and the structure thereof can be seen with reference to FIG. 2, which will not be repeated herein. In this embodiment, the polarizer 240 in FIG. 2 is directly used in the LCD 400 as the upper polarizer 430.

The LCD display unit 410 at least includes a first substrate, a second substrate. The upper polarizer 430 is located on a surface of the first substrate, the lower polarizer 420 is located on a surface of the second substrate, and the first substrate and the second substrate are disposed in opposite directions and are sandwiched with the liquid crystal. The LCD display unit 410 displays images and forms a touch display with touch functions together with the upper polarizer 430, the contact layer 210, and the intermediate layer 220.

During the process, the circuits required by the touch panel are directly formed on the upper polarizer 430, the touch panel is then formed by adhering the upper polarizer 430, the contact layer 210, and the intermediate layer 220, and the touch panel is directly adhered on the surface of the LCD display unit 410. In such manner, the process of adhering the touch panel and the-upper polarizer can be omitted, and at the same time, the glass substrate of the conventional touch panel can be eliminated. Thus, the LCD 400 is lighter and thinner.

### Fourth Embodiment

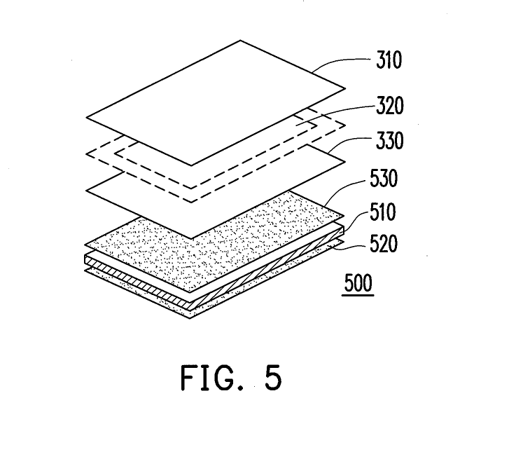

FIG. 5 is a structure diagram of a touch LCD according to a fourth embodiment of the present invention. Referring to FIG. 3 together, this embodiment further illustrates the structure relationship between a capacitive touch panel and an LCD panel. An LCD 500 includes a lower polarizer 520, an LCD display unit 510, an upper polarizer 530, a conductive layer 330, an electrode pattern layer 320, and a protective layer 310, wherein the touch panel is formed by the upper polarizer 530, the conductive layer 330, the electrode pattern layer 320 and the protective layer 310. And the structure thereof can be seen with reference to FIG. 2, which will not be repeated herein. In this embodiment, the polarizer 340 in FIG. 3 is directly used in the LCD 500 as the upper polarizer 530.

The LCD display unit 510 at least includes a first substrate, and a second substrate. The upper polarizer 530 is located on the first substrate, the lower polarizer 520 is located under the second substrate, and the first substrate and the second substrate are disposed in opposite directions and are sandwiched with the liquid crystal. The LCD display unit 510 can be used to display images and form a touch LCD with touch functions together with the upper polarizer 530, the conductive layer 330, the electrode pattern layer 320, and the protective layer 310.

During the process, the touch panel can be directly formed by adhering the upper polarizer 530, the conductive layer 330, the electrode pattern layer 320, and the protective layer 310, and the touch panel is then directly adhered onto the surface of the LCD display unit 5i 0. In such manner, the process of adhering the touch panel and the upper polarizer can be omitted, and at the same time, the glass substrate of the conventional touch panel can be eliminated. Thus, the LCD 500 is lighter and thinner.

In view of above, a polarizer is used instead of a glass substrate of the touch panel in the embodiments. The structure of the touch panel is directly formed on the polarizer, so as to eliminate a layer of glass substrate and the conventional adhering process between the glass substrate of the touch panel and the upper polarizer. Thereby, the adhesion between the touch panel and the liquid crystal panel is improved, and the touch LCD is lighter and thinner.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A touch panel, comprising:
a polarizer, having a plurality of first electrodes;
a contact layer, having a plurality of second electrodes; and
an intermediate layer, disposed between the polarizer and the contact layer.

2. The touch panel as claimed in claim 1, wherein the material of the contact layer comprises PET film, glass or polymer film, and the second electrodes are formed on a surface of the contact layer.

3. The touch panel as claimed in claim 1, wherein the first electrodes are formed on a surface of the polarizer.

4. The touch panel as claimed in claim 1, wherein the material of the first electrodes comprises indium tin oxide.

5. The touch panel as claimed in claim 1, wherein the material of the second electrodes comprises indium tin oxide.

6. The touch panel as claimed in claim 1, wherein the first electrodes and the second electrodes are disposed in opposite directions and are perpendicular to each other.

7. The touch panel as claimed in claim 1, wherein the intermediate layer comprises a plurality of spacer dots for spacing the polarizer and the contact layer.

8. A touch panel, comprising:
a polarizer;
a conductive layer, disposed on a polarizer;
an electrode pattern layer, wherein the electrode pattern layer has a plurality of first electrodes and second electrodes on upper and lower surfaces thereof respectively, and the electrode pattern layer is disposed on the conductive layer; and
a protective layer, disposed on the electrode pattern layer, for protecting the electrode pattern layer.

9. The touch panel as claimed in claim 8, wherein the material of the protective layer comprises PET film.

10. The touch panel as claimed in claim 8, wherein the material of the electrode pattern layer comprises glass, and the first electrodes and the second electrodes are respectively formed on the upper and the lower surfaces of the electrode pattern layer.

11. The touch panel as claimed in claim 8, wherein the material of the first electrodes comprises ITO.

12. The touch panel as claimed in claim 8, wherein the material of the second electrodes comprises ITO.

13. A touch liquid crystal display (LCD), comprising:
a lower polarizer;
an LCD display unit, disposed on the lower polarizer;
an upper polarizer, disposed on the LCD display unit, and the upper polarizer has a plurality of first electrodes on a surface opposite to the LCD display unit;
a contact layer, having a plurality of second electrodes, and disposed on the upper polarizer; and
an intermediate layer, disposed between the upper polarizer and the contact layer, for spacing the first electrodes and the second electrodes.

14. The touch LCD as claimed in claim 13, wherein the LCD display unit at least comprises a first substrate and a second substrate, the upper polarizer is located on the first substrate, the lower polarizer is located under the second substrate, and the first substrate and the second substrate are disposed in opposite directions and are sandwiched with the liquid crystal.

15. The touch LCD as claimed in claim 13, wherein the material of the contact layer comprises PET film, glass or polymer film, and the second electrodes are formed on a surface of the contact layer.

16. The touch LCD as claimed in claim 13, wherein the first electrodes are formed on a surface of the upper polarizer.

17. The touch LCD as claimed in claim 13, wherein the material of the first electrodes comprises ITO.

18. The touch LCD as claimed in claim 13, wherein the material of the second electrodes comprises ITO.

19. The touch LCD as claimed in claim 13, wherein the first electrodes and the second electrodes are disposed in opposite directions and are perpendicular to each other.

20. The touch LCD as claimed in claim 13, wherein the intermediate layer comprises a plurality of spacer dots, for spacing the polarizer and the contact layer.

21. A touch LCD, comprising:
a lower polarizer;
an LCD display unit, disposed on the lower polarizer;
an upper polarizer, disposed on the LCD display unit;
a conductive layer, disposed on the upper polarizer;
an electrode pattern layer, wherein the electrode pattern layer has a plurality of first electrodes and second electrodes on upper and lower surfaces thereof respectively, and the electrode pattern layer is disposed on the conductive layer; and
a protective layer, disposed on the electrode pattern layer, for protecting the electrode pattern layer.

22. The touch LCD as claimed in claim 21, wherein the LCD display unit at least comprises a first substrate and a second substrate, the upper polarizer is located on the first substrate, the lower polarizer is located under the second substrate, and the first substrate and the second substrate are disposed in opposite directions and are sandwiched with the liquid crystal.

23. The touch LCD as claimed in claim 21, wherein the material of the protective layer comprises PET film.

24. The touch LCD as claimed in claim 21, wherein the material of the electrode pattern layer comprises glass, and the first electrodes and second electrodes are respectively formed on upper and lower surfaces of the electrode pattern layer.

25. The touch LCD as claimed in claim 21, wherein the material of the first electrodes comprises ITO.

26. The touch LCD as claimed in claim 21, wherein the material of the second electrodes comprises ITO.

27. The touch LCD as claimed in claim 21, wherein the first electrodes and the second electrodes are disposed in opposite directions and are perpendicular to each other.
